(19) United States
(12) Patent Application Publication
(10) Pub. No.: US 2006/0163567 A1
(43) Pub. Date: Jul. 27, 2006

(54) Semiconductor electrode, method of manufacturing the same, and solar cell employing the same

(75) Inventors: Sang-cheol Park, Seoul (KR); Jung-gyu Nam, Yongin-si (KR); Won-cheol Jung, Seoul (KR); Young-jun Park, Suwon-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Suwon-si (KR)

(21) Appl. No.: 11/336,818

(22) Filed: Jan. 23, 2006

(30) Foreign Application Priority Data
Jan. 24, 2005 (KR) 10-2005-0006348

(51) Int. Cl. H01L 29/10

(52) U.S. Cl. 257/43

(57) ABSTRACT

Provided are a continuous-phase semiconductor electrode that can provide better photoelectric conversion efficiency by improving a pathway for electron transport, a method of manufacturing the same, and a solar cell employing the same. The semiconductor electrode includes a transparent conductive electrode, formed on a substrate, including a metal or a metal nitride; and a metal oxide layer continuously formed on the transparent conductive electrode.

### CROSS-REFERENCE TO RELATED PATENT APPLICATION

Priority is claimed to Korean Patent Application No. 10-2005-0006348, filed on Jan. 24, 2005, in the Korean Intellectual Property Office, the disclosure of which is incorporated herein in its entirety by reference.

1. Field of the Invention

The present invention relates to a continuous-phase semiconductor electrode, a method of manufacturing the same, and a solar cell employing the same. More particularly, the present invention relates to a continuous-phase semiconductor electrode that can provide better photoelectric conversion efficiency by improving a pathway for electron transport, a method of manufacturing the same, and a solar cell employing the same.

2. Description of the Related Art

In light of pending energy problems, various studies to find alternatives to fossil fuels have been conducted. In particular, research has been conducted into applications of natural energy sources such as wind power, nuclear power, or solar power to replace petroleum, stocks of which are expected to be depleted within several decades. Among these natural energy sources, solar energy used for solar cells is an unlimited and environmental-friendly energy source, unlike many of the other energy sources. Selenium (Se) solar cells were first developed in 1983. Since then, silicon solar cells have attracted widespread interest.

However, silicon solar cells have not been widely applied due to high manufacturing costs. Also, many difficulties are involved in energy efficiency enhancement of the silicon solar cells. In view of these problems, much interest has been focused on the development of dye-sensitized solar cells having low manufacturing costs.

Unlike silicon solar cells, dye-sensitized solar cells are photoelectrochemical solar cells that primarily use photosensitive dye molecules capable of generating electron-hole pairs by absorbing visible light, and a transition metal oxide transporting the generated electrons to an electrode. Graetzel cells developed by Graetzel et al. from Switzerland in 1991 are representative of commonly known dye-sensitized solar cells. The Graetzel cells include a semiconductor electrode made of dye molecule-coated titanium dioxide (TiO₂) nanoparticles, an opposite electrode made of platinum, and an electrolyte filled between the two electrodes. The Graetzel cells offer lower manufacturing costs (per power) than conventional silicon solar cells and thus have attracted widespread interest as promising substitutes for conventional solar cells.

Such a dye-sensitized solar cell is illustrated FIG. 1. Referring to FIG. 1, the dye-sensitized solar cell includes a semiconductor electrode 10, an electrolyte layer 13, and an opposite electrode 14. The semiconductor electrode 10 includes a transparent conductive substrate 11 and a photoreceptive layer 12. That is, the dye-sensitized solar cell is structured such that the electrolyte layer 13 is filled between the semiconductor electrode 10 and the opposite electrode 14.

Generally, the photoreceptive layer 12 includes a metal oxide 12a and a dye 12b. The dye 12b can be represented by S (neutral state), S* (transition state), and S⁺ (ion state). A dye molecule, after absorbing sunlight, generates electron-hole pairs by electron transition from the ground state (S/S⁺) to the excited state (S*/S⁺). Excited electrons (e−) are injected to the conduction band (CB) of the metal oxide 12a to generate an electromotive force.

However, all electrons in the excited state are not injected to the conduction band of the metal oxide 12a. That is, some electrons in the excited state are returned to the ground state by recombination with a dye molecule, or alternatively, electrons injected to the conduction band are recombined with a redox couple in an electrolyte, thereby lowering photoelectric conversion efficiency, resulting in a reduction in electromotive force. Thus, a need to improve the photoelectric conversion efficiency of a solar cell by enhancing the electroconductivity of an electrode through less recombination reaction of electrons has been identified as a major issue.

In particular, when forming a metal oxide layer using nanoparticles, an interface between the nanoparticles acts as a resistor, thereby lowering electroconductivity, resulting in a reduction in photoelectric conversion efficiency. That is, when metal oxide nanoparticles are printed or directly grown on a transparent conductive substrate to manufacture an electrode, an interlayer interface is formed, and thus, electric resistance is increased. As a result, the above-described electronic recombination reaction occurs, thereby lowering the photoelectric conversion efficiency of a solar cell. Such interlayer interface formations are illustrated in FIGS. 2 and 3. Referring to FIGS. 2 and 3, voids are present between nanoparticles or nanotubes and a substrate, and thus, the nanoparticles or the nanotubes do not directly contact the substrate.

U.S. Pat. Nos. 6,270,571 and 6,649,824 disclose a metal oxide layer in the form of wires or nanotubes. In this case, however, the above-described interlayer interface is unavoidably formed, thereby increasing resistance. As a result, the recombination reaction of electrons cannot be efficiently controlled and thus reduction in photoelectric conversion efficiency is involved.

Therefore, it is necessary to develop a new method capable of reducing resistance by improving an interface between a transparent conductive substrate and a metal oxide layer to thereby prevent the recombination reaction of electrons, resulting in an increase in photoelectric conversion efficiency.

### SUMMARY OF THE INVENTION

Aspects of the present invention provide a semiconductor electrode with better photoelectric conversion efficiency through less recombination reaction.

Another aspect of the present invention also provides a method of manufacturing the semiconductor electrode.

Yet another aspect of the present invention provide a solar cell employing the semiconductor electrode.

According to an aspect of the present invention, there is provided a semiconductor electrode including: a transparent conductive electrode, formed on a substrate, including a metal or a metal nitride; and a metal oxide layer continuously formed on the transparent conductive electrode.

The metal may be at least one selected from the group consisting of titanium, niobium, hafnium, indium, tin, and zinc.

The metal nitride may be at least one selected from the group consisting of titanium nitride, niobium nitride, hafnium nitride, indium nitride, tin nitride, and zinc nitride.

Metal oxide of the metal oxide layer may be at least one selected from the group consisting of titanium oxide, niobium oxide, hafnium oxide, indium oxide, tin oxide, and zinc oxide.

Metal oxide of the metal oxide layer may be a nano-material selected from quantum dots, nanodots, nanotubes, nanowires, nanobelts, or nanoparticles.

The metal may be the same metal as used for the metal oxide layer and the metal nitride may be a nitride of the same metal as used for the metal oxide layer.

The semiconductor electrode may further include a dye. The dye may be bound to metal oxide of the metal oxide layer continuously formed on the transparent conductive electrode.

The semiconductor electrode may further include a metal oxide layer between the transparent conductive electrode and the substrate.

The semiconductor electrode may further include a metal oxide nanoparticle layer on the metal oxide layer.

According to another aspect of the present invention, there is provided a method of manufacturing the semiconductor electrode, which includes: coating a metal or a metal nitride on a substrate; and forming a metal oxide layer through surface oxidation of the metal or the metal nitride.

According to yet another aspect of the present invention, there is provided a solar cell including the semiconductor electrode, an electrolyte layer, and an opposite electrode.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic view illustrating a conventional dye-sensitized solar cell;

FIG. 2 is a sectional view showing a contact interface between a substrate and titanium dioxide nanotubes according to a conventional technique;

FIG. 3 is a sectional view showing a contact interface between a substrate and titanium dioxide nanoparticles according to a conventional technique;

FIG. 4 is a schematic view illustrating an oxidation process (anodic aluminum oxidation) of metal nitride performed in Example 1;

FIG. 5 is a transmission electron microscopic (TEM) image showing an interlayer contact interface in a semiconductor electrode manufactured in Example 1;

FIG. 6 is an enlarged TEM image of the interlayer contact interface of FIG. 5;

FIG. 7 is a surface image of the semiconductor electrode manufactured in Example 1; and

FIG. 8 is a surface image of a semiconductor electrode manufactured in Example 4.

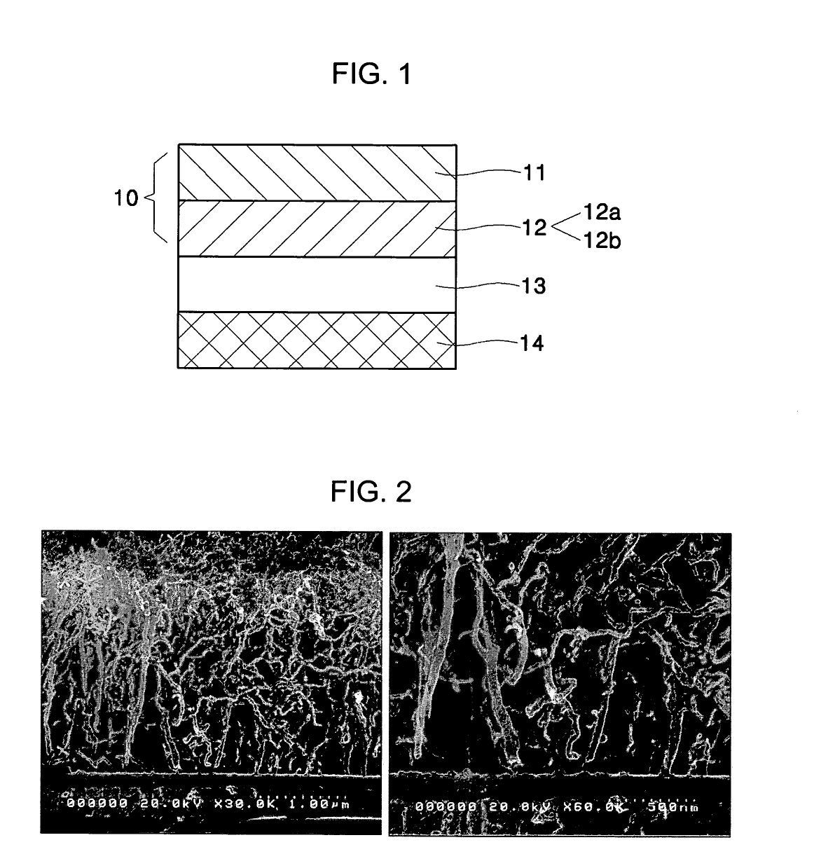

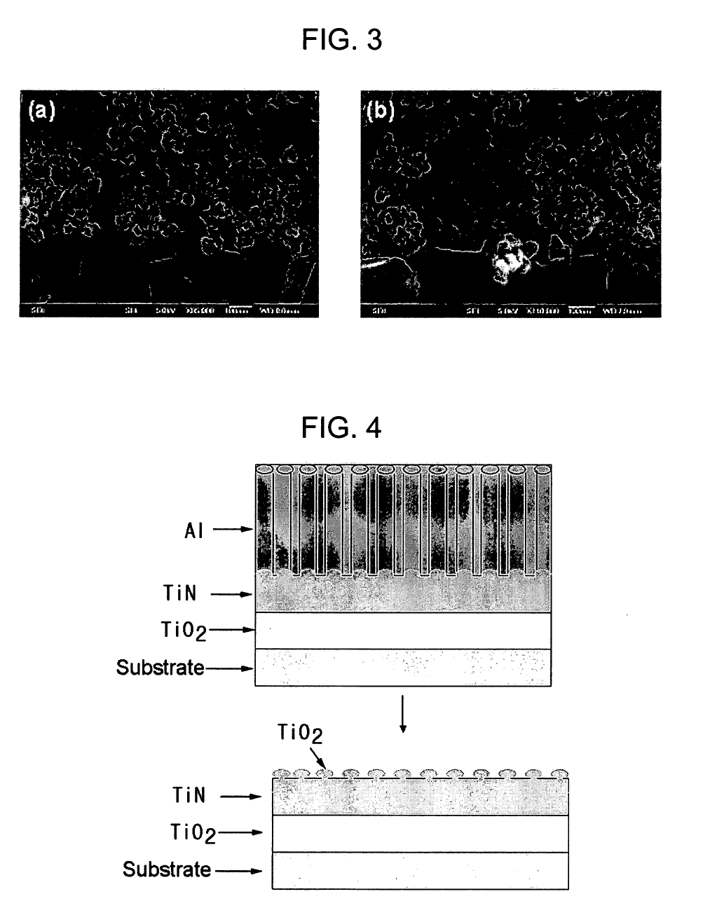

### DETAILED DESCRIPTION OF THE INVENTION

The present invention will now be described more fully with reference to the accompanying drawings, in which exemplary embodiments of the invention are shown.

An exemplary semiconductor electrode according to the present disclosure includes a transparent conductive electrode, formed on a substrate, including a metal or a metal nitride; and a metal oxide layer continuously formed on the transparent conductive electrode.

With respect to a metal oxide layer formed on a transparent conductive electrode using metal oxide nanoparticles, etc., it is common that an interface between the nanoparticles and the transparent conductive electrode acts as a resistor due to an incomplete interfacial contact, thereby lowering electroconductivity. In contrast, in the semiconductor electrode of the present disclosure, the metal oxide layer is continuously formed on the transparent conductive electrode, and thus, an interface between the metal oxide layer and the transparent conductive electrode is hardly formed, thereby providing remarkably low electric resistance. Therefore, electrons injected into the metal oxide layer from outside the semiconductor electrode can be easily transported to the transparent conductive electrode without an interfacial contact. That is, in the semiconductor electrode of the present disclosure, interfacial resistance due to an interfacial contact between a metal oxide layer and a transparent conductive electrode, which is unavoidably involved in a conventional semiconductor electrode, hardly occurs, and thus electron transport to the conductor transparent electrode is facilitated, resulting in a reduction in electron accumulation and recombination reaction.

The transparent conductive electrode of the present disclosure includes, selectively, a metal and a metal nitride. The metal may be at least one selected from the group consisting of titanium, niobium, hafnium, indium, tin, and zinc, and the metal nitride may be at least one selected from the group consisting of titanium nitride, niobium nitride, hafnium nitride, indium nitride, tin nitride, and zinc nitride. More preferably, the metal is niobium, indium, or tin, and the metal nitride is titanium nitride, hafnium nitride, or zinc nitride. It is preferable that the metal and the metal nitride are selected considering light transmittance. For example, with respect to titanium, since the light transmittance of titanium nitride is better than that of metal titanium, it is preferable to use titanium nitride. In the case of using pure metal, the pure metal may be coated to be thinner than its nitride to obtain a desired light transmittance.

The metal or the metal nitride serves as a transparent conductive film, and at the same time, as an electrode allowing electrons received from the metal oxide layer to pass through a closed circuit added thereto. The metal nitride has a lower resistance than indium tin oxide (ITO) that has been representatively used as a transparent conductive film, and thus, can facilitate electron transport. Therefore, electron accumulation is prevented, and thus a recombination reaction where electrons are returned to the outside can be maximally controlled. Thus, the metal nitride can be used as a useful substitute for ITO.

When used in a solar cell, the metal or the metal nitride needs to have appropriate light transmittance. For this, it is necessary to coat the metal or the metal nitride to an appropriate thickness. Even when the metal or the metal nitride has good light transmittance, if the thickness of a layer made of the metal or the metal nitride is too thick, light transmittance may be undesirably reduced. Thus, it is preferable that the metal or the metal nitride is coated to a thickness of about 5 nm to 1 μm on the substrate. A metal or metal nitride coating with a thickness less than 5 nm may be unsuitable for a transparent conductive film. On the other hand, if the thickness of the metal or the metal nitride exceeds 1 μm, light transmittance may be lowered.

The metal oxide layer is continuously formed on the conductive transparent electrode including the metal or the metal nitride. As used herein, the phrase “the metal oxide layer is continuously formed on the transparent conductive electrode” indicates that the metal oxide layer is formed on the transparent conductive electrode without an interfacial contact. The metal oxide for the metal oxide layer thus formed is not particularly limited, but may be an n-type semiconductor wherein conduction band electrons serve as carriers for providing anode current in an excited state.

An interfacial contact resistance between the metal oxide layer and the transparent conductive electrode including the metal or the metal nitride, when measured using a 4-probe method, is 1KΩ/μm or less, preferably 0.00001 to 1KΩ/μm, which is significantly lower than several to tens of MΩ/cm which is an incomplete interfacial contact resistance. Therefore, the recombination reaction of electrons can be maximally prevented, thereby enhancing photoelectric conversion efficiency.

Metal oxide satisfying the above requirements may be at least one selected from the group consisting of titanium oxide, niobium oxide, hafnium oxide, indium oxide, tin oxide, and zinc oxide. These metal oxides can be used alone or in combination of two or more. Titanium oxide (TiO₂) is preferable.

To allow a dye adsorbed onto a surface of the metal oxide layer to absorb a lot of light and to enhance adsorption between an electrolyte layer and the metal oxide layer, it is preferable to increase the surface area of the metal oxide layer. Thus, the metal oxide of the metal oxide layer may be a nano-material selected from quantum dots, nanodots, nanotubes, nanowires, nanobelts, or nanoparticles.

The metal oxide layer must allow light transmitted through the transparent conductive electrode to pass therethrough and sufficiently adsorb a dye and an electrolyte layer. In this regard, it is preferable to form the metal oxide layer to a thickness of about 1 to 30 μm. If the thickness of the metal oxide layer is less than 1 μm, electron generation may be insufficient in the excited state and a dye and an electrolyte layer may be insufficiently adsorbed. On the other hand, if it exceeds 30 μm, light transmittance may be reduced and a pathway for electron transport may be increased.

To continuously form the transparent conductive electrode and the metal oxide layer, i.e., to integrally form the transparent conductive electrode and the metal oxide layer, it is preferable that the transparent conductive electrode and the metal oxide layer are formed using the same metal. For example, when the metal nitride constituting the transparent conductive electrode is titanium nitride (TiN), the metal oxide constituting the metal oxide layer may be titanium oxide (TiO₂).

Nanoparticles may be further coated on the metal oxide layer. That is, metal oxide nanoparticles which are the same as or different from the metal oxide of the metal oxide layer may be further coated on the metal oxide layer to further provide a surface area elevation effect, and thus to increase adsorption for a dye and an electrolyte layer. For this, nanoparticles may be coated on a surface of the metal oxide layer continuously formed on the transparent conductive electrode, followed by thermal treatment.

The semiconductor electrode of the present invention may further include a dye on the metal oxide layer. Such dye particles are adsorbed onto a surface of the metal oxide layer and generate electron-hole pairs through electron transition from the ground state (S/S⁺) to the excited state (S*/S⁺) by absorbing light. The excited electrons (e−) are injected to the conduction band of the metal oxide layer and then transported to the transparent conductive electrode to thereby generate an electromotive force.

The dye is not limited provided that it is commonly used in the solar cell field. Preferably, the dye is a ruthenium complex. However, the dye is not particularly limited provided that it has a charge separation function and a sensitization action. In addition to the ruthenium complex, the dye may be a xanthine dye such as rhodamine B, rose bengal, eosin, and erythrosin; a cyanine dye such as quinocyanine and cryptocyanine; a basic dye such as phenosafranine, cabri blue, thiosine, and methylene blue; a porphyrin compound such as chlorophyll, zinc porphyrin, and magnesium porphyrin; an azo dye; a phthalocyanine compound; a complex compound such as ruthenium trisbipyridyl complex; an anthraquinone dye; or a polycyclic quinone dye. These dye compounds can be used alone or in combination of two or more. The ruthenium complex may be RuL₂(SCN)₂, RuL₂(H₂O)₂, RuL₃, or RuL₂ where L is 2,2′-bipyridyl-4,4′-dicarboxylate.

An exemplary semiconductor electrode of the present invention may further include a metal oxide layer between the substrate and the transparent conductive electrode including the metal or the metal nitride. The metal oxide layer can be formed on the substrate using a common coating method, e.g., sputtering or chemical deposition. The metal oxide layer primarily serves to enhance light transmittance. In addition, due to its higher resistance than the transparent conductive electrode, the metal oxide layer serves as a blocking film allowing electrons injected into the transparent conductive electrode to be transported to an external circuit.

Metal oxide used for the metal oxide layer between the transparent conductive electrode and the substrate may be an oxide of a metal which is the same as or different from a metal used for the transparent conductive electrode. For example, the metal oxide used for the metal oxide layer between the transparent conductive electrode and the substrate may be at least one selected from the group consisting of titanium oxide, niobium oxide, hafnium oxide, indium oxide, tin oxide, and zinc oxide. The metal oxide layer may be formed to a thickness of 5 nm to 1 μm. If the thickness of the metal oxide layer is outside the above range, light transmittance may be reduced.

The present disclosure also provides a method of manufacturing a semiconductor electrode, which includes: coating a metal or a metal nitride on a substrate; and forming a metal oxide layer by surface oxidation of the metal or the metal nitride.

Coating the metal or the metal nitride on the substrate may be performed using a common coating method, e.g., sputtering, chemical deposition, or physical deposition. The metal or the metal nitride can be coated to a sufficient thickness considering the subsequent surface oxidation. Thus, the metal or the metal nitride may be coated to a thickness of 1 to 30 μm.

The surface oxidation of the metal or the metal nitride to form the metal oxide layer may be performed by AAO (Anodic Aluminum Oxidation), thermal treatment, or nanoprinting.

With respect to the AAO method, an aluminum film is formed on the metal or the metal oxide. The resultant structure is placed in a low-temperature electrolyte solution such as sulfuric acid or oxalic acid and current is applied thereto. As a result, uniformly porous, periodically arranged aluminum oxide arrays are formed in the aluminum film. The aluminum oxide arrays are used as templates for fabrication of metal oxide nanodots. Through the aluminum oxide arrays, metal oxide nanodots are grown from a surface of the metal or the metal nitride. When the metal oxide nanodots are thermally treated at a temperature of 80 to 500° C. for 0.1 to 2 hours, more uniform metal oxide can be formed on the surface of the metal or the metal nitride. The metal oxide thus formed has a nanodot structure with a projecting nanodot surface, and thus an increased surface area. Therefore, a dye and an electrolyte layer can be more efficiently adsorbed onto a surface of the metal oxide.

With respect to the thermal treatment, a surface of the metal or the metal nitride may be thermally treated under air atmosphere at a temperature of 80 to 500° C. for 0.1 to 2 hours.

The substrate is not particularly limited provided that it has transparency. A glass substrate, a silica substrate, etc. can be used.

The method of the present invention may further include forming a metal oxide layer between the metal or the metal nitride and the substrate. In this case, prior to coating the metal or the metal nitride on the substrate, an oxide of a metal which is the same as or different from the metal or the metal nitride can be coated on the substrate by sputtering, deposition, etc. The metal oxide layer between the metal or the metal nitride and the substrate may have a thickness of about 1 nm to 1 μm.

An exemplary method of the present invention may further include forming a metal oxide nanoparticle layer on the metal oxide layer formed on the surface of the metal or the metal nitride to increase a surface area of metal oxide. In this case, the metal oxide nanoparticle layer can be formed using a common coating method. For example, a colloid solution is prepared by hydrothermal synthesis using a metal oxide precursor and a solvent and then coated on the metal oxide layer, followed by sintering so that contact and filling between metal oxide nanoparticles occur, to obtain a metal oxide nanoparticle layer as a sintered body.

The metal oxide precursor may be an alkoxide compound of a transition metal, etc. In the case of forming a titanium oxide layer, titanium (IV) isopropoxide can be used, but the present invention is not limited thereto. The solvent may be an acid such as an acetic acid but the present invention is not limited thereto. The sintering may be performed at a temperature of 80 to 550° C.

An exemplary semiconductor electrode of the present invention can be used in a dye-sensitized solar cell because it prevents a recombination reaction and facilitates electron transport, thereby enhancing photoelectric conversion efficiency. Thus, various embodiments of the present invention also provides a dye-sensitized solar cell including a semiconductor electrode, an electrolyte layer, and an opposite electrode.

The electrolyte layer includes an electrolyte solution. The electrolyte solution may be an iodine acetonitrile solution, an N-methylpyrrolidone (NMP) solution, 3-methoxypropionitrile, etc., but the present invention is not limited thereto. The electrolyte solution is not limited provided that it has a hole transport function.

The opposite electrode is not limited provided that it is made of a conductive material. However, provided that a conductive layer is formed on an opposite side to the semiconductor electrode, the opposite electrode may also be made of an insulating material. It is preferable to use an electrode made of an electrochemically stable material as the opposite electrode. Preferably, the opposite electrode may be made of platinum, gold, or carbon. Furthermore, it is preferable that an opposite side to the semiconductor substrate has a fine structure to increase a surface area for the purpose of enhancing a redox catalytic effect. In this regard, it is preferable that the opposite electrode made of platinum is in a platinum black state and the opposite electrode made of carbon is in a porous state. The platinum black state can be formed by anode oxidation using platinum or platinum chloride acid treatment, and the porous state can be formed by sintering carbon microparticles or an organic polymer.

An exemplary method of manufacturing a dye-sensitized solar cell with the above-described structure according to the present invention is not particularly limited and thus may be any method commonly known in the pertinent art.

Hereinafter, the present invention will be described more specifically with reference to the following Examples and Comparative Examples. The following Examples are for illustrative purposes and are not intended to limit the scope of the invention.

### EXAMPLE 1

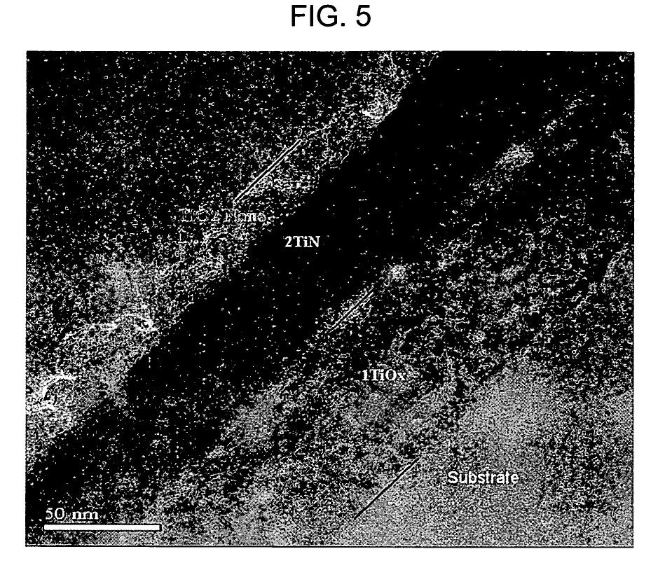

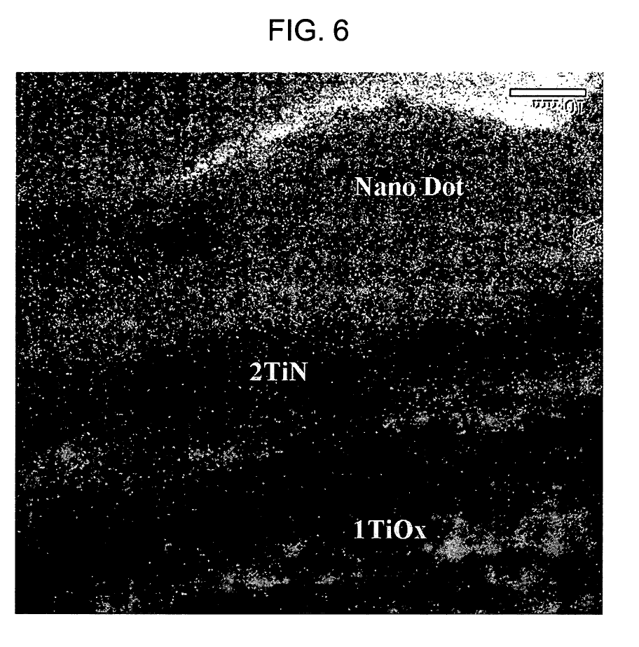

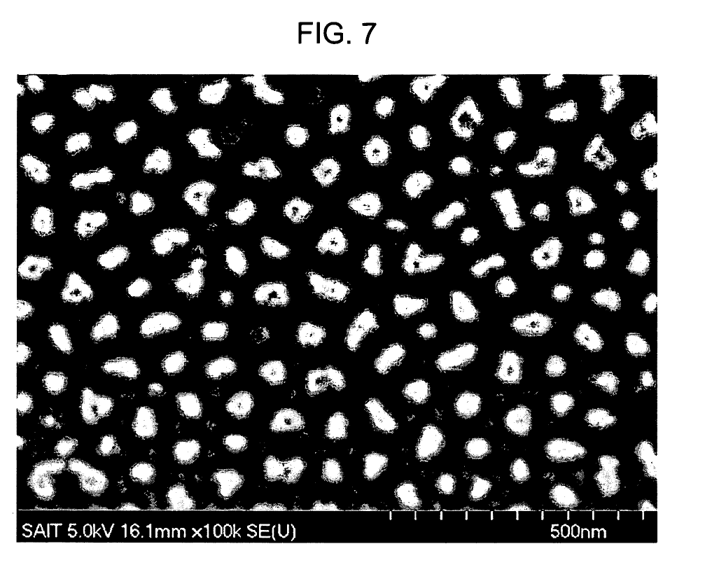

TiO₂ was coated to a thickness of 75 nm on a glass substrate by sputtering. TiN was then coated to a thickness of about 5 μm on the TiO₂ layer by sputtering. Al was then coated to a thickness of 300 nm on the TiN layer by sputtering. Nanodots were grown from the resultant structure used as a basic sample by AAO as shown in FIG. 4. At this time, the basic sample was placed in a 0.3M sulfuric acid solution and a voltage of 19 V at −15° C. was applied thereto. Then, Al was removed and the resultant structure was thermally treated at 400° C. for one hour to form an electrode composed of substrate/TiO₂/TiN/TiO₂. The thicknesses of the lower TiO₂ layer, the TiN layer, and the upper TiO₂ layer were respectively 75 nm, 53 nm, and 5 μm. The TEM sectional image of the electrode is shown in FIGS. 5 and 6. FIG. 6 is an enlarged TEM image of the section of FIG. 5. Referring to the TEM images of FIGS. 5 and 6, all the layers were continuously formed without forming an interface. FIG. 7 shows a surface image of the electrode. Referring to FIG. 7, nanodots were uniformly formed on a surface of the substrate.

Next, the electrode was dipped in a 0.3 mM ruthenium dithiocyanate 2,2′-bipyridyl-4,4′-dicarboxylate solution for 24 hours and dried to thereby manufacture a semiconductor electrode wherein a dye was adsorbed onto the substrate.

### EXAMPLE 2

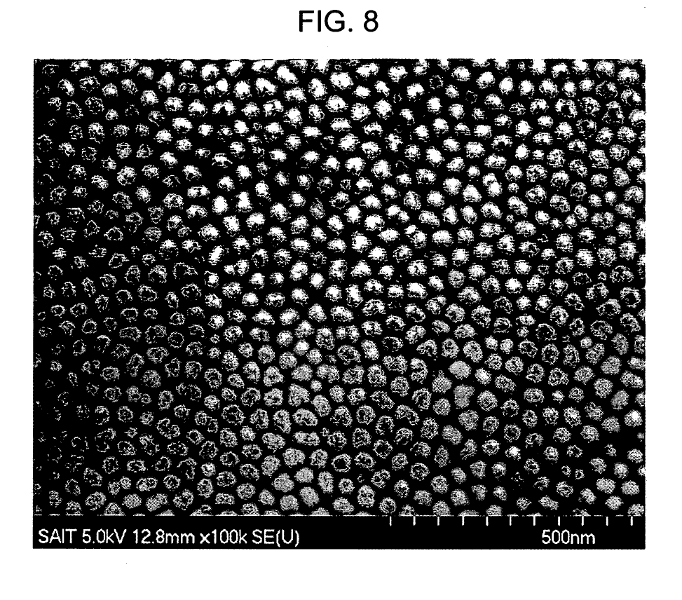

A semiconductor electrode was manufactured in the same manner as in Example 1 except that an oxalic acid was used instead of sulfuric acid. A surface TEM image of the semiconductor electrode prior to adsorbing a dye is shown in FIG. 8. Referring to FIG. 8, more dense and compact nanodots were formed, as compared to the semiconductor electrode manufactured using sulfuric acid.

### EXAMPLE 3

A semiconductor electrode was manufactured in the same manner as in Example 1 except that the formation of the TiO₂ layer on the glass substrate by sputtering was omitted.

### EXAMPLE 4

TiO₂ was coated to a thickness of 50 nm on a glass substrate by sputtering. TiN was then coated to a thickness of about 50 nm on the TiO₂ layer by sputtering. Al was then coated to a thickness of 300 nm on the TiN layer by sputtering. Nanodots were grown from the resultant structure used as a basic sample by AAO. At this time, the basic sample was placed in a 0.3M sulfuric acid solution and a voltage of 19 V at −15° C. was applied thereto. Then, Al was removed and the resultant structure was thermally treated at 400° C. for one hour to form an electrode composed of substrate/TiO₂/TiN/TiO₂.

A titanium dioxide colloid solution was prepared by hydrothermal synthesis using titanium isopropoxide and acetic acid in an autoclave that had been set to 220° C. A solvent was evaporated from the titanium dioxide colloid solution until the content of titanium dioxide was 12 wt % to thereby obtain a concentrated colloid solution containing titanium dioxide with a nanoscale particle size (about 5 to 30 nm). Then, hydroxypropyl cellulose (Mw: 80,000) was added to the concentrated colloid solution and the resultant solution was stirred for 24 hours to make a titanium dioxide coating slurry. Then, the titanium dioxide coating slurry was coated on the electrode using a doctor blade method and thermally treated at about 450° C. for one hour so that contact and filling between the titanium dioxide nanoparticles except an organic polymer occurred to thereby manufacture an electrode having thereon titanium dioxide nanoparticles with a thickness of about 2 μm.

Next, the electrode was dipped in a 0.3 mM ruthenium dithiocyanate 2,2′-bipyridyl-4,4′-dicarboxylate solution for 24 hours and dried to thereby manufacture a semiconductor electrode wherein a dye was adsorbed onto the substrate.

### EXAMPLES 5-8

An opposite electrode was manufactured by coating an ITO-doped transparent conductive glass substrate with platinum. The opposite electrode was used as an anode and each semiconductor electrode manufactured in Examples 1-4 was used as a cathode, and the opposite electrode and each semiconductor electrode were assembled. At this time, the opposite electrode and each semiconductor electrode were assembled so that conductive surfaces faced with each other, i.e., the platinum layer of the opposite electrode and the metal oxide layer of each semiconductor electrode faced with each other. The two electrodes were closely adhered to each other on an about 100-140° C. heating plate by means of a polymer layer made of SURLYN (manufactured by DuPont) having a thickness of about 40 microns as an intermediate layer between the two electrodes under about 1-3 atm. The SURLYN polymer was adhered to the surfaces of the two electrodes by heat and pressure.

Next, a space defined by the two electrodes was filled with an electrolyte solution through micropores formed on the surface of the opposite electrode to thereby complete dye-sensitized solar cells according to the present invention. The electrolyte solution was an I₃⁻/I⁻ electrolyte solution obtained by dissolving 0.6M 1,2-dimethyl-3-octyl-imidazolium iodide, 0.2M LiI, 0.04M I₂, and 0.2M 4-tert-butylpyridine (TBP) in acetonitrile.

### COMPARATIVE EXAMPLE 1

A titanium dioxide colloid solution was prepared by hydrothermal synthesis using titanium isopropoxide and acetic acid in an autoclave that had been set to 220° C. A solvent was evaporated from the colloid solution until the content of titanium dioxide was 12 wt % to obtain a concentrated colloid solution containing titanium dioxide with a nanoscale particle size (about 5 to 30 nm). Next, hydroxypropyl cellulose (Mw: 80,000) was added to the concentrated colloid solution and the resultant solution was stirred for 24 hours to make a titanium dioxide coating slurry. Then, the titanium dioxide coating slurry was coated on a glass substrate coated with ITO using a doctor blade method and heated at about 450° C. for one hour so that the contact and filling between titanium dioxide nanoparticles except an organic polymer occurred to thereby obtain a transparent conductive electrode having thereon a titanium dioxide layer with a thickness of about 4 microns.

Next, the transparent conductive electrode was dipped in a 0.3 mM ruthenium dithiocyanate 2,2′-bipyridyl-4,4′-dicarboxylate solution for 24 hours and dried to thereby manufacture a semiconductor electrode wherein a dye was adsorbed onto the substrate.

### COMPARATIVE EXAMPLE 2

A dye-sensitized solar cell was manufactured in the same manner as in Example 5 using the semiconductor electrode manufactured in Comparative Example 1.

### EXPERIMENTAL EXAMPLE 1

Interfacial contact resistances of the semiconductor electrodes manufactured in Examples 1 and 3 and Comparative Example 1 were measured.

In connection with the semiconductor electrodes of Examples 1 and 3, a contact resistance was measured using a closed circuit composed of the TiN layer, which was a transparent conductive film, and the overlying TiO₂ layer. The contact resistance was 200Ω/cm. In connection with the semiconductor electrode of Comparative Example 1, a contact resistance was measured using a closed circuit composed of the ITO layer, which was a transparent conductive film, and the overlying TiO₂ layer. The contact resistance was 10 MΩ/cm.

That is, the semiconductor electrodes of Examples 1 and 3 exhibited a remarkably reduced contact resistance and thus better electroconductivity due to continuous formation of the TiO₂ layer on the TiN layer, as compared to the semiconductor electrode of Comparative Example 1.

### EXPERIMENTAL EXAMPLE 2

To evaluate the photoelectric conversion efficiency of the dye-sensitized solar cells manufactured in Examples 5-8 and Comparative Example 2, photovoltage and photocurrent of the dye-sensitized solar cells were measured.

A xenon lamp (Oriel, 01193) was used as an optical source. The solar conditions (AM 1.5) of the xenon lamp were corrected using a standard solar cell (Frunhofer Institute Solare Engeriessysteme, Certificate No. C-ISE369, Type of material: Mono-Si+KG filter) to plot a photocurrent-photovoltage curve. The photoelectric conversion efficiency was calculated using the photocurrent-photovoltage curve according to the following equation and the results are presented in Table 1 below.
ηₑ=(V_{oc}I_{sc}FF)/(P_{inc})

ηₑ=photoelectric conversion efficiency, I_{sc}=current density, V_{oc}=voltage, FF=fill factor, and P_{inc}=100 mw/cm² (1sun).

TABLE 1

| Section | Photoelectric conversion efficiency (%) |
|---|---|
| Example 5 | 5.1 |
| Example 6 | 5.2 |
| Example 7 | 5.0 |
| Example 8 | 5.3 |
| Comparative Example 2 | 3.5 |

From Table 1, it can be seen that in a dye-sensitized solar cell including a semiconductor electrode according to exemplary embodiments of the present invention, an interfacial contact resistance is reduced, and thus a recombination reaction is prevented and electron transport is facilitated, thereby improving total photoelectric conversion efficiency.

A semiconductor electrode according to the present invention includes a continuous phase of a transparent conductive film and a metal oxide layer, and thus can prevent a recombination reaction and facilitate electron transport, thereby providing better photoelectric conversion efficiency. Therefore, the semiconductor electrode can be usefully adopted in a dye-sensitized solar cell.

The present invention has been described by exemplary embodiments to which it is not limited. Variations and modifications will occur to those skilled in the art that do not depart from the scope of the invention as recited in the claims appended hereto.

What is claimed is:

1. A semiconductor electrode comprising:
a transparent conductive electrode, formed on a substrate, comprising a metal or a metal nitride; and
a metal oxide layer continuously formed on the transparent conductive electrode.

2. The semiconductor electrode of claim 1, wherein a contact resistance between the transparent conductive electrode and the metal oxide layer is 1KΩ/μm or less.

3. The semiconductor electrode of claim 1, wherein the metal is at least one selected from the group consisting of titanium, niobium, hafnium, indium, tin, and zinc.

4. The semiconductor electrode of claim 1, wherein the metal nitride is at least one selected from the group consisting of titanium nitride, niobium nitride, hafnium nitride, indium nitride, tin nitride, and zinc nitride.

5. The semiconductor electrode of claim 1, wherein metal oxide of the metal oxide layer is at least one selected from the group consisting of titanium oxide, niobium oxide, hafnium oxide, indium oxide, tin oxide, and zinc oxide.

6. The semiconductor electrode of claim 1, wherein metal oxide of the metal oxide layer is a nano-material selected from the group consisting of quantum dots, nanodots, nanotubes, nanowires, nanobelts, or nanoparticles.

7. The semiconductor electrode of claim 1, wherein the metal is the same metal as used for the metal oxide layer and the metal nitride is a nitride of the same metal as used for the metal oxide layer.

8. The semiconductor electrode of claim 1, further comprising a dye, wherein the dye is formed on the metal oxide layer continuously formed on the transparent conductive electrode.

9. The semiconductor electrode of claim 1, further comprising a metal oxide layer between the substrate and the transparent conductive electrode.

10. The semiconductor electrode of claim 1, further comprising a metal oxide nanoparticle layer on the metal oxide layer.

11. A method of manufacturing a semiconductor electrode, which comprises:
coating a metal or a metal nitride on a substrate; and
forming a metal oxide layer through surface oxidation of the metal or the metal nitride.

12. The method of claim 11, wherein the forming of the metal oxide layer is performed by anodic aluminum oxidation (AAO), thermal treatment, or nanoprinting.

13. The method of claim 11, further comprising forming a metal oxide layer on the substrate.

14. The method of claim 11 further comprising forming a metal oxide nanoparticle layer on the metal oxide layer.

15. A dye-sensitized solar cell comprising:
the semiconductor electrode of claim 1;
an electrolyte layer; and
an opposite electrode.

16. A dye-sensitized solar cell comprising:
the semiconductor electrode of claim 2;
an electrolyte layer; and
an opposite electrode.

17. A dye-sensitized solar cell comprising:
the semiconductor electrode of claim 3;
an electrolyte layer; and
an opposite electrode.

18. A dye-sensitized solar cell comprising:
the semiconductor electrode of claim 4;
an electrolyte layer; and
an opposite electrode.

19. A dye-sensitized solar cell comprising:
the semiconductor electrode of claim 5;
an electrolyte layer; and
an opposite electrode.

20. A dye-sensitized solar cell comprising:
the semiconductor electrode of claim 6;
an electrolyte layer; and
an opposite electrode.
